(19) United States
(12) Patent Application Publication
(10) Pub. No.: US 2008/0048269 A1
(43) Pub. Date: Feb. 28, 2008

(54) METHOD OF FABRICATING STRUCTURE FOR INTEGRATED CIRCUIT INCORPORATING HYBRID ORIENTATION TECHNOLOGY AND TRENCH ISOLATION REGIONS

(75) Inventors: Xiangdong Chen, Poughquag, NY (US); Yong Meng Lee, Singapore (SG)

Correspondence Address: HOFFMAN, WARNICK & D'ALESSANDRO LLC, 75 STATE ST, 14TH FL, ALBANY, NY, 12207, US

(73) Assignees: INTERNATIONAL BUSINESS MACHINES CORPORATION, Armonk, NY (US); CHARTERED SEMICONDUCTOR MANUFACTURING LTD. ("CSM"), Singapore (SG)

(21) Appl. No.: 11/467,325

(22) Filed: Aug. 25, 2006

(51) Int. Cl. H01L 29/94

(52) U.S. Cl. 257/368; 257/E29.003; 257/E21.036

(57) ABSTRACT

An embodiment of the present invention discloses a method of fabricating a structure for an integrated circuit incorporating hybrid orientation technology (HOT) and trench isolation regions. The structure of the integrated circuit comprising: a substrate with a first silicon layer of a first crystalline orientation and a second silicon layer, of a second crystalline orientation different from the first crystalline orientation, disposed on the first silicon layer; a dielectric layer on the substrate; a first silicon active trench region, having first crystalline orientation, extending to the first silicon layer; a second silicon active trench region, having the second crystalline orientation, extending to the second silicon layer, the first silicon active region electrically isolated from the second silicon active region by a portion of the dielectric layer; a first transistor on the first silicon active region; and a second transistor on the second silicon active region.

### BACKGROUND OF THE INVENTION

1. Technical Field

The invention relates generally to integrated circuits (IC). Particularly, to a method of fabricating and a structure of an IC incorporating hybrid (mixed) orientation technology (HOT) FETs and trench isolation regions.

2. Background Art

As the size of electronic devices shrink with a concomitant demand for increased performance, the diminishing critical dimensions (CD) limits the optimal performance due to reduced contacts which compromise the electrical connectivity within integrated circuits (ICs). In particular, the diminishing widths of entire regions in an IC affect the isolation of the active regions (RX). This trend is particularly evident for technology with dimensions of 45 nm and smaller.

Conventionally, ICs are formed using a mixture of interconnected N-channel and P-channel field effect transistors (FETs). Usually, a silicon material of crystalline orientation <100> is used for fabricating N-channel FETs due to the high electron mobility in such a crystalline lattice allowing higher speeds to be achieved. While a silicon material of crystalline orientation <110> is used for fabricating P-channel FETs which enhances the mobility of holes available in such a crystalline lattice.

Recent development in MOSFET fabrication technology has brought about hybrid/mixed orientation technology (HOT) in which N-channel FETs and P-channel FETs may be combined on a single substrate having different crystalline orientation surfaces. The combination of having both N-channel and P-channel field effect transistors (FETs) within a single integrated circuit device provides versatility that enables greater flexibility in IC design. Current fabrication methods use silicon etching and an epitaxy process to incorporate the two different crystalline orientations on a single substrate. However, such fabrication processes are costly. In addition, the resulting narrowness between active regions presents poor electrical isolation in currently available HOT substrates.

In view of the foregoing, there is a need in the art for a solution to the problems of the related art.

### SUMMARY OF THE INVENTION

An embodiment of the present invention discloses a method of fabricating a structure for an integrated circuit incorporating hybrid orientation technology (HOT) and trench isolation regions. The structure of the integrated circuit includes: a substrate with a first silicon layer of a first crystalline orientation and a second silicon layer of a second crystalline orientation different from the first crystalline orientation, disposed on the first silicon layer; a dielectric layer on the substrate; a first silicon active trench region, having first crystalline orientation, extending to the first silicon layer; a second silicon active trench region, having the second crystalline orientation, extending to the second silicon layer, the first silicon active region electrically isolated from the second silicon active region by a portion of the dielectric layer; a first transistor on the first silicon active region; and a second transistor on the second silicon active region.

A first aspect of the present invention includes an integrated circuit comprising: a substrate including a first silicon layer having a first crystalline orientation and a second silicon layer on the first silicon layer, the second silicon layer having a second crystalline orientation different than the first crystalline orientation; a dielectric layer on the substrate; a first silicon active trench region extending from a surface of the dielectric layer to the first silicon layer, the first silicon active trench region having the first crystalline orientation; a second silicon active trench region extending from the surface of the dielectric layer to the second silicon layer, the second silicon active trench region having the second crystalline orientation, the first silicon active region electrically isolated from the second silicon active region by a portion of the dielectric layer; a first transistor on the first silicon active region; and a second transistor on the second silicon active region.

A second aspect of the present invention includes a method for fabricating an integrated circuit, the method comprising: providing a first silicon layer of a first crystalline orientation; depositing a second silicon layer of a second crystalline orientation on the first silicon layer; depositing a barrier layer on a portion of the second silicon layer; depositing a dielectric layer to cover the second silicon layer and the barrier layer; forming a first trench by etching through the dielectric layer and the second silicon layer to expose the first silicon layer; forming a second trench by etching through the dielectric layer and the barrier layer to expose the second silicon layer; filling the first trench with a silicon material of the first crystalline orientation; filing the second trench with a silicon material of the second crystalline orientation; forming a first transistor by coupling a first gate to the silicon material of the first crystalline orientation in the first trench; and forming a second transistor by coupling a second gate to the silicon material of the second crystalline orientation in the second trench.

A third aspect of the present invention includes an integrated circuit device comprising: a first transistor including a gate atop a first silicon trench region that extends into a first silicon layer, each of the first trench region and first silicon layer, having a first crystalline orientation; a second transistor including a gate atop a second silicon trench region that extends into a second silicon layer, each of the second silicon trench region and the second silicon layer, having a second crystalline orientation; a dielectric region disposed at least partially between the first transistor and the second transistor; wherein the second silicon layer is at least partially adjacent to the first silicon layer; and wherein the first crystalline orientation is different from the second crystalline orientation.

The illustrative aspects of the present invention are designed to solve the problems herein described and other problems not discussed which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 is a cross-sectional view of a substrate with a first silicon layer and a second silicon layer of an embodiment of the present invention.

FIG. 2A is a cross-sectional view of the substrate in FIG. 1 with a barrier layer in an embodiment of the present invention.

FIG. 2B is a cross-sectional view of the substrate in FIG. 2A with a portion of the barrier layer etched.

FIG. 3 is a cross-sectional view of FIG. 2B with an added dielectric layer.

FIG. 4 is a cross-sectional view of FIG. 3 with two trenches etched into the dielectric layer.

FIG. 5 is a cross-sectional view of FIG. 4 with one of the two trenches etched into the first silicon layer.

FIG. 6 is a cross-sectional view of FIG. 5 with the remaining trench etched into the barrier layer.

FIG. 7 is a cross-sectional view of FIG. 6 with both trenches lined and filled.

FIG. 8 is a cross-sectional view of the complete IC of an embodiment of the present invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

One embodiment of the invention includes an integrated circuit (IC) or IC device 10 (FIG. 8) having a structure combining trench isolation regions and a hybrid/mixed orientation technology (HOT) substrate. An embodiment of the invention also provides a method for fabricating the IC where silicon materials of differing crystalline orientations are incorporated into the IC to form field effect transistors (FETs) of opposing electrical characteristics.

FIG. 8 illustrates an embodiment of the structure of the IC device 10 of the present invention. One embodiment of the method of the present invention is described with reference to FIG. 1-7, which illustrate one embodiment of a method of fabricating IC 10 incorporating the unique combination of trench isolation regions and a HOT substrate.

FIG. 1 shows a substrate 12 with a first silicon layer 100 having a crystalline orientation, <100>, while a second silicon layer 110 is disposed on top of first silicon layer 100. Second silicon layer 110 has a crystalline orientation, <110>. While the two particular crystalline orientations, <100> and <110>, are illustrated, other crystalline orientations maybe used so long as they are different from one another.

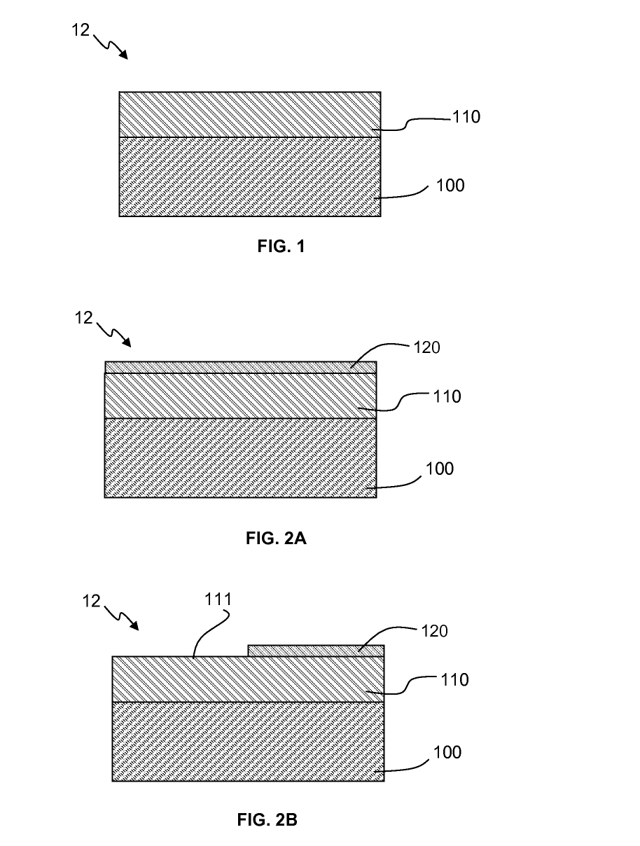

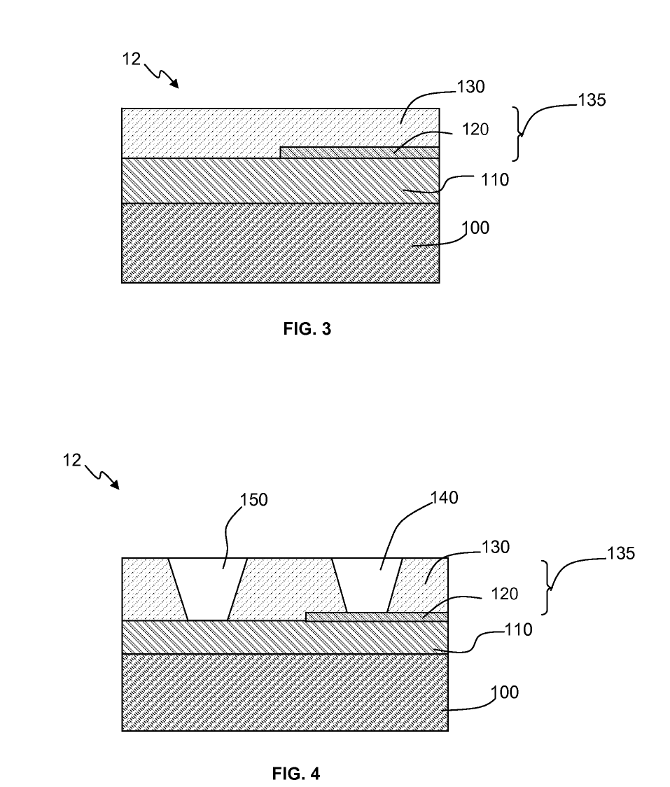

As shown in FIG. 2A, a barrier layer 120 including, for example, silicon nitride or any other common barrier layer material is disposed on second silicon layer 110. FIG. 2B shows that following the deposition of barrier layer 120, a portion of the barrier layer is etched leaving a portion of second silicon layer 111 exposed.

As shown in FIG. 3, on top of exposed second silicon layer 111 and remaining barrier layer 120 is disposed a dielectric layer 130 such as silicon oxide or any other common dielectric material. Barrier layer 120 and dielectric layer 130 form an isolation region 135.

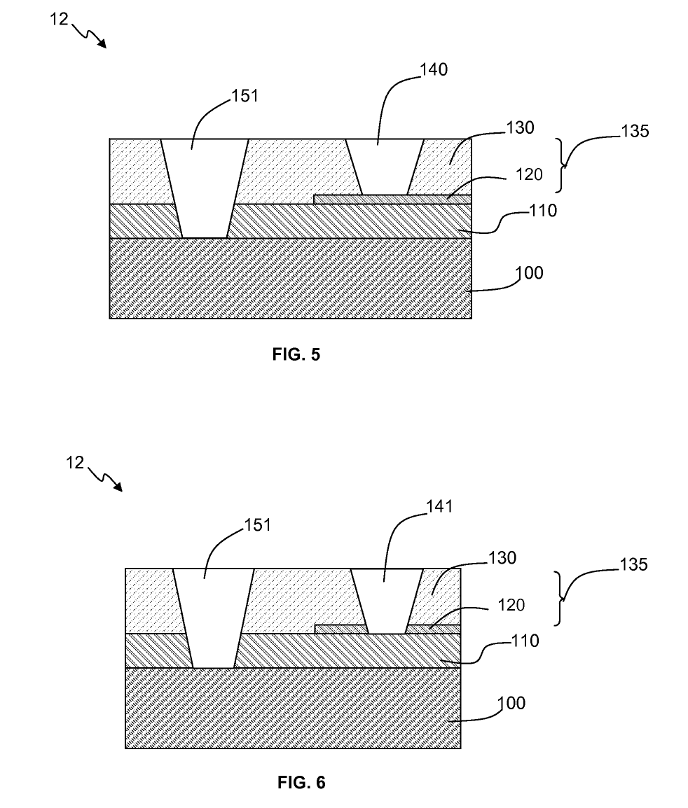

FIG. 4 shows two trenches 140 and 150 etched through dielectric layer 130, where trench 140 stops on barrier layer 120 and trench 150 stops on second silicon layer 110.

FIG. 5 shows further etching is performed in trench 150 (FIG. 4) to form new trench 151 such that the etching continues through second silicon layer 110 until first silicon layer 100 is exposed. Thus, trench 151 stops on first silicon layer 100 having crystalline orientation <100>.

Continuous etching of trench 140 results in new trench 141, shown in FIG. 6, where barrier layer 120 at the bottom of trench 140 (FIG. 5) is etched away to expose second silicon layer 110, with crystalline orientation, <110>.

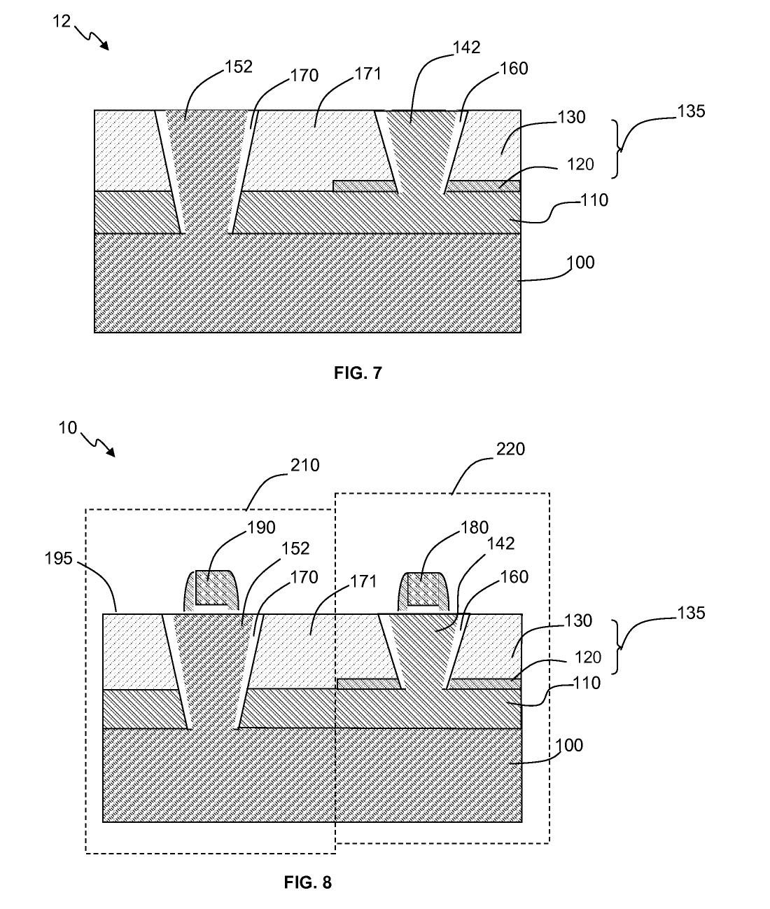

FIG. 7 shows that each trench 141 and 151 has sidewalls that may be lined with a liner layer 160, 170 including, for example, a silicon nitride layer and/or silicon oxide layer 160, 170. Hence, trenches 141 and 151, have respectively lined walls 160 and 170. Following an epitaxy process, each respective trench 141 and 151 (FIG. 6) is filled with silicon material of crystalline orientation matching the silicon material exposed at their respective bottoms to form silicon active trench regions 142 and 152, respectively. Silicon material may include silicon, silicon germanium or any other silicon materials upon which transistors may be formed. As shown in FIG. 7, for example, trench 141 (FIG. 6) is filled with silicon material of orientation, <110>; and trench 151 (FIG. 6) is filled with silicon material of orientation, <100>. Dielectric layer 130 and barrier layer 120 provide electrical isolation between substantially inverted T-shaped silicon active trench regions 142 and 152 forming a wide trench isolation region 171 between the bottoms of silicon active trench regions 142 and 152. The wide trench isolation region 171 provides improved isolation that enables broadening of bottoms of substantially inverted T-shaped silicon active trench regions 142 and 152.

As shown in FIG. 8, gates 180 and 190 are formed atop silicon active trench regions 142 and 152, respectively, after completion of epitaxy and chemical mechanical polishing (CMP) process to form hybrid/mixed orientation MOSFETs. Gates 180 and 190 may be fabricated from gate material like polysilicon, metal or silicide, and maybe formed using any now known or later developed techniques.

FIG. 8 also shows an IC or IC device 10 formed from the fabrication process described above. The resultant IC 10 includes a first and a second field effect transistor (FET) 210 and 220, respectively. First FET 210 has a first silicon active trench region 152 extending from a surface 195 of dielectric layer 130 to first silicon layer 100; and second FET has a second silicon active trench region 142 extending from surface 195 of dielectric layer 130 to second silicon layer 110, where isolation region 135 is disposed between first and second silicon active trench regions 152 and 142. First FET 210 has a distinct electrical characteristic from that of second FET 220. That is, one maybe an N-channel FET (NFET) and one may be a P-channel FET (PFET). The respective opposing crystalline orientations (i.e., <100> and <110>) of silicon materials in the (silicon) active trench regions 152 and 142 improve performance of the device formed thereon. Each FET 210, 220 is electrically coupled to silicon material of the same orientation in respective first silicon layer 100 and second silicon layer 110. Silicon active region trenches 142 and 152 each have lined walls 160 and 170, respectively.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. An integrated circuit (IC) comprising:
a substrate including a first silicon layer having a first crystalline orientation and a second silicon layer on the first silicon layer, the second silicon layer having a second crystalline orientation different than the first crystalline orientation;
a dielectric layer on the substrate;
a first silicon active trench region extending from a surface of the dielectric layer to the first silicon layer, the first silicon active trench region having the first crystalline orientation;
a second silicon active trench region extending from the surface of the dielectric layer to the second silicon layer, the second silicon active trench region having the second crystalline orientation, the first silicon active region electrically isolated from the second silicon active region by a portion of the dielectric layer;
a first transistor on the first silicon active region; and
a second transistor on the second silicon active region.

2. The integrated circuit of claim 1, further comprising a barrier layer between a portion of the first silicon layer and the second silicon layer, wherein the second silicon active trench region extends through the barrier layer.

3. The integrated circuit of claim 2, wherein the barrier layer includes silicon nitride.

4. The integrated circuit of claim 1, wherein each silicon active trench region includes a liner layer therein.

5. The integrated circuit of claim 4, wherein the liner layer includes at least one of silicon oxide and silicon nitride.

6. The integrated circuit of claim 1, wherein the first transistor includes an N-channel field effect transistor (NFET) and the first crystalline orientation is <100>, and the second transistor includes a P-channel field effect transistor (PFET) and the second crystalline orientation is <110>.

7. The integrated circuit of claim 1, wherein the first silicon layer with the first silicon active region have a substantially inverted T-shaped, and wherein the second silicon layer with the second silicon active region have a substantially inverted T-shaped.

8. The integrated circuit of claim 7, wherein each uppermost part of the substantially inverted T-shape is larger than each lowermost part of the substantially inverted T-shape.

9. A method for fabricating an integrated circuit, the method comprising:
providing a first silicon layer of a first crystalline orientation;
depositing a second silicon layer of a second crystalline orientation on the first silicon layer;
depositing a barrier layer on a portion of the second silicon layer;
depositing a dielectric layer to cover the second silicon layer and the barrier layer;
forming a first trench by etching through the dielectric layer and the second silicon layer to expose the first silicon layer;
forming a second trench by etching through the dielectric layer and the barrier layer to expose the second silicon layer;
filling the first trench with silicon material of the first crystalline orientation;
filing the second trench with silicon material of the second crystalline orientation;
forming a first transistor by coupling a first gate to the silicon material of the first crystalline orientation in the first trench; and
forming a second transistor by coupling a second gate to the silicon material of the second crystalline orientation in the second trench.

10. The method of claim 9, wherein each filling includes epitaxial growth.

11. The method of claim 9, further comprising lining the first and second trench with a liner layer.

12. The method of claim 11, wherein the liner layer includes at least one of the following: silicon nitride and silicon oxide.

13. The method of claim 9, wherein the first transistor is electrically isolated from the second transistor.

14. The method of claim 13, wherein the first transistor is selected from a group consisting of: an N-channel field effect transistor and a P-channel field effect transistor.

15. The method of claim 13, wherein the second transistor is selected from a group consisting of: a P-channel field effect transistor and a N-channel field effect transistor.

16. The method of claim 9, wherein the first silicon layer and the first trench are electrically connected.

17. The method of claim 9, wherein the second silicon layer and the second trench are electrically connected.

18. An integrated circuit device (IC) comprising:
a first transistor including a gate atop a first silicon trench region that extends to a first silicon layer, each of the first trench region and the first silicon layer having a first crystalline orientation;
a second transistor including a gate atop a second silicon trench region that extends to a second silicon layer, each of the second silicon trench region and the second silicon layer having a second crystalline orientation;
a dielectric layer disposed at least partially between the first transistor and the second transistor;
wherein the second silicon layer is at least partially adjacent to the first silicon layer; and
wherein the first crystalline orientation is different from the second crystalline orientation.

19. The integrated circuit device of claim 18, wherein each of the first crystalline orientation and the second crystalline orientation is selected from a group consisting of: <100> and <110>.

20. The integrated circuit device of claim 18, wherein the first silicon trench region with the first silicon layer and the second trench region with the second silicon layer are each substantially inverted T-shaped.
